(19) United States
(12) Patent Application Publication
(10) Pub. No.: US 2017/0092618 A1
(43) Pub. Date: Mar. 30, 2017

(54) PACKAGE TOPSIDE BALL GRID ARRAY FOR ULTRA LOW Z-HEIGHT

(71) Applicant: INTEL CORPORATION, SANTA CLARA, CA (US)

(72) Inventor: David Huitink, Chandler, AZ (US)

(21) Appl. No.: 14/864,616

(22) Filed: Sep. 24, 2015

(51) Int. Cl. H01L 25/065; H01L 23/498; H01L 23/373; H01L 23/367; H01L 25/00; H01L 23/42; H01L 23/31; H01L 21/56; H01L 21/48; H01L 23/00; H01L 23/538

(52) U.S. Cl. CPC H01L 25/0657; H01L 24/09; H01L 23/49816; H01L 23/3736; H01L 23/367; H01L 23/5384; H01L 23/42; H01L 23/3157; H01L 24/89; H01L 21/563; H01L 21/4871; H01L 25/50; H01L 2924/1434; H01L 2924/1432; H01L 2224/08238; H01L 2224/89; H01L 2924/182; H01L 2924/15321

(57) ABSTRACT

Embodiments of the present disclosure describe integrated circuit (IC) package assemblies having top-side connection pads, computing devices incorporating the IC package assemblies, methods for formation of the IC package assemblies, and associated configurations. An IC package assembly may include a substrate having a first side and a second side opposite the first side, an IC die coupled with the first side of the substrate, a plurality of connection pads coupled with the first side of the substrate, and a plurality of interconnect structures coupled with the plurality of connection pads. Other embodiments may be described and/or claimed.

### TECHNICAL FIELD

The present disclosure relates generally to the field of packages for electronic devices, and more specifically to package to printed circuit board (PCB) mounting configurations.

### BACKGROUND

Mobile devices, tablets, and other computing devices demand thin designs and good thermal management. Processor dies are typically attached to printed circuit boards within these devices such that the dies are coupled with a top side of a substrate and a back side of the substrate is coupled with the printed circuit board.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 schematically illustrates a cross-sectional side view of an integrated circuit (IC) package assembly that may include package top-side connection pads, in accordance with various embodiments.

FIG. 2 schematically illustrates a cross-sectional side view of a board mounting configuration for an IC package that includes top-side connection pads, in accordance with various embodiments.

FIG. 3 schematically illustrates a top view of a board mounting configuration for an IC package that includes top-side connection pads, in accordance with various embodiments.

FIG. 4 schematically illustrates a flow diagram for a process of fabricating an IC package assembly such as the IC package assembly of FIG. 1 and mounting it in a board mounting configuration such as that shown in FIGS. 2 and 3, in accordance with various embodiments.

FIG. 5 schematically illustrates a computing device that may include the IC package assembly of FIG. 1 and/or the board mounting configuration of FIG. 2 or 3, in accordance with various embodiments.

### DETAILED DESCRIPTION

Embodiments herein may include integrated circuit (IC) package assemblies having top-side connection pads, computing devices incorporating the IC package assemblies, methods for formation of the IC package assemblies, and associated configurations. An IC package assembly may include a substrate having a first side and a second side opposite the first side, an IC die coupled with the first side of the substrate, a plurality of connection pads coupled with the first side of the substrate, and a plurality of interconnect structures coupled with the plurality of connection pads.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other.

In various embodiments, the phrase “a first layer formed on a second layer” may mean that the first layer is formed over the second layer, and at least a part of the first layer may be in direct contact (e.g., direct physical and/or electrical contact) or indirect contact (e.g., having one or more other layers between the first layer and the second layer) with at least a part of the second layer.

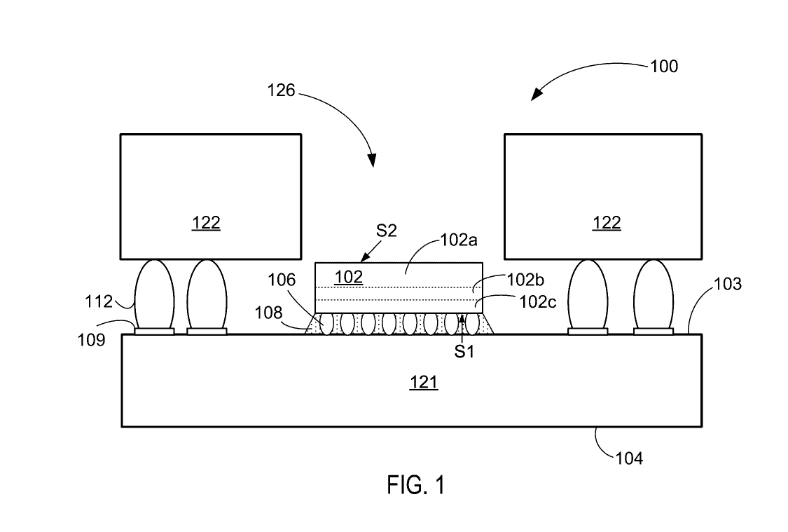

FIG. 1 schematically illustrates a cross-sectional side view of an IC package assembly 100, in accordance with some embodiments. In some embodiments, the IC assembly 100 may include one or more dies (hereinafter “die 102”) electrically and/or physically coupled with a top side 103 of a package assembly 121 (sometimes referred to as a “package substrate”). In some embodiments, the top side 103 of the package assembly 121 may be electrically coupled with a circuit board 122. This is in contrast to a typical configuration where a bottom side 104 of the package assembly 121 may be electrically coupled with the circuit board 122. In some embodiments, coupling the top side rather than the bottom side may provide for a decreased thickness, or z-height, of the package assembly and increased thermal performance in small form factor (SFF) designs when configured with a PCB having a die cavity.

The die 102 may represent a discrete product made from a semiconductor material (e.g., silicon) using semiconductor fabrication techniques such as thin film deposition, lithography, etching, and the like used in connection with forming complementary metal-oxide-semiconductor (CMOS) devices. In some embodiments, the die 102 may be, include, or be a part of a radio frequency (RF) die. In other embodiments, the die may be, include, or be a part of a processor, memory, system-on-chip (SoC), or application specific integrated circuit (ASIC).

In some embodiments, an underfill material 108 (sometimes referred to as an “encapsulant”) may be disposed between the die 102 and the package assembly 121 to promote adhesion and/or protect features of the die 102 and the package assembly 121. The underfill material 108 may be composed of an electrically insulative material and may encapsulate at least a portion of the die 102 and/or die-level interconnect structures 106. In some embodiments, the underfill material 108 may be in direct contact with the die-level interconnect structures 106.

The die 102 may be attached to the package assembly 121 according to a wide variety of suitable configurations including, for example, being directly coupled with the package assembly 121 in a flip-chip configuration, as depicted. In the flip-chip configuration, an active side, S1, of the die 102 including active circuitry is attached to a surface of the package assembly 121 using die-level interconnect structures 106 such as bumps, pillars, or other suitable structures that may also electrically couple the die 102 with the package assembly 121. The active side S1 of the die 102 may include transistor devices, and an inactive side, S2, may be disposed opposite to the active side S1.

The die 102 may generally include a semiconductor substrate 102a, one or more device layers (hereinafter “device layer 102b”), and one or more interconnect layers (hereinafter “interconnect layer 102c”). The semiconductor substrate 102a may be substantially composed of a bulk semiconductor material such as, for example, silicon, in some embodiments. The device layer 102b may represent a region where active devices such as transistor devices are formed on the semiconductor substrate 102a. The device layer 102b may include, for example, structures such as channel bodies and/or source/drain regions of transistor devices. The interconnect layer 102c may include interconnect structures that are configured to route electrical signals to or from the active devices in the device layer 102b. For example, the interconnect layer 102c may include trenches and/or vias to provide electrical routing and/or contacts. In some embodiments, one or more electrically functional through-silicon vias (TSVs) (not shown) may extend through the interconnect layer 102c, the device layer 102b, and the semiconductor substrate 102a such that additional circuitry (not shown) and/or dies (not shown) may be coupled with the inactive side S2 of the die 102 and may extend into the PCB die cavity when the package assembly 121 is mounted to the PCB.

In some embodiments, the die-level interconnect structures 106 may be configured to route electrical signals between the die 102 and other electrical devices. The electrical signals may include, for example, input/output (I/O) signals and/or power/ground signals that are used in connection with operation of the die 102. In various embodiments, a plurality of conductive top-side connection pads 109 may be located on the top side 103 of the package assembly 121. In some embodiments, one or more of the top-side connection pads 109 may be electrically coupled with one or more of the die-level interconnect structures 106.

In some embodiments, the package assembly 121 may include a multi-layer package assembly with integrated components for wireless communication. The wireless communication may include, for example, short range wireless data transfer between portable devices and/or wireless displays or high speed wireless communication between peer devices. In some embodiments, the package assembly 121 may include one or more dielectric structures.

The package assembly 121 may include electrical routing features (not shown in FIG. 1) such as, for example, traces, pads, through-holes, vias, or lines configured to route electrical signals to or from the die 102. For example, the package assembly 121 may be configured to route electrical signals between the die 102 and components for wireless communication that are integrated within the package assembly, or between the die 102 and the circuit board 122, or between the die 102 and another electrical component (e.g., another die, interposer, interface, component for wireless communication, etc.) coupled with the package assembly 121.

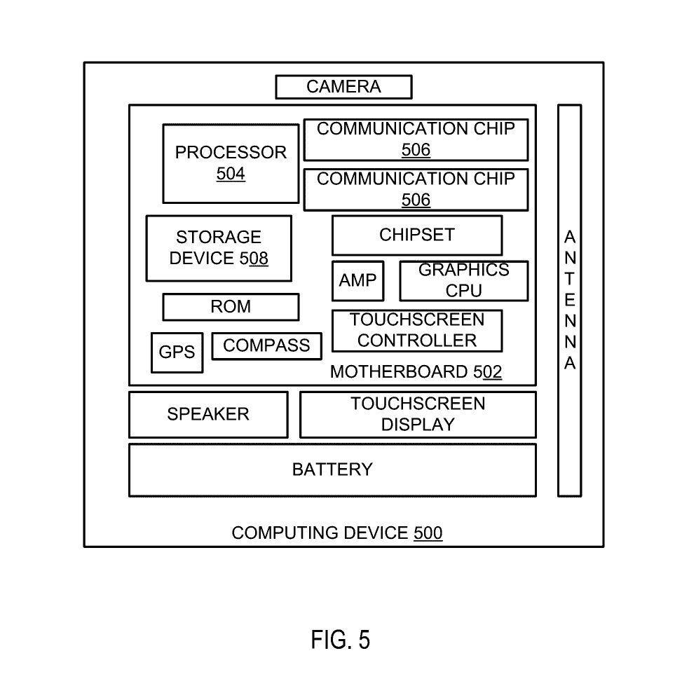

The circuit board 122 may be a printed circuit board (PCB) composed of an electrically insulative material such as an epoxy laminate. For example, the circuit board 122 may include electrically insulating layers composed of materials, such as polytetrafluoroethylene, phenolic cotton paper materials such as Flame Retardant 4 (FR-4), FR-1, cotton paper, and epoxy materials or composite epoxy material (CEM) such as CEM-1 or CEM-3, or woven glass materials that are laminated together using an epoxy resin prepreg material. Interconnect structures (not shown) such as traces, trenches or vias may be formed through the electrically insulating layers to route the electrical signals of the die 102 through the circuit board 122. The circuit board 122 may be composed of other suitable materials in other embodiments. In some embodiments, the circuit board 122 may be a motherboard or other PCB in a computing device (e.g., motherboard 502 of FIG. 5).

Package-level interconnects, such as solder balls 112, may be coupled with the package assembly 121 and/or the circuit board 122 to form corresponding solder joints that are configured to further route the electrical signals between the package assembly 121 and the circuit board 122. In some embodiments, the solder balls 112 may be coupled with the top-side connection pads 109 and the circuit board 122. The package level interconnects may be arranged in a regular pattern such as a ball grid array (BGA) in various embodiments. Other suitable techniques to physically and/or electrically couple the package assembly 121 with the circuit board 122 may be used in other embodiments. In various embodiments, the circuit board 122 may be structured to have a die cavity 126 formed therein such that when the package assembly is coupled with the circuit board 122, the die 102 is located below and/or within the die cavity 126.

The IC assembly 100 may include a wide variety of other suitable configurations in other embodiments including, for example, suitable combinations of flip-chip and/or wire-bonding configurations, interposers, multi-chip package configurations including system-in-package (SiP) and/or package-on-package (PoP) configurations. Other suitable techniques to route electrical signals between the die 102 and other components of the IC package assembly 100 may be used in some embodiments.

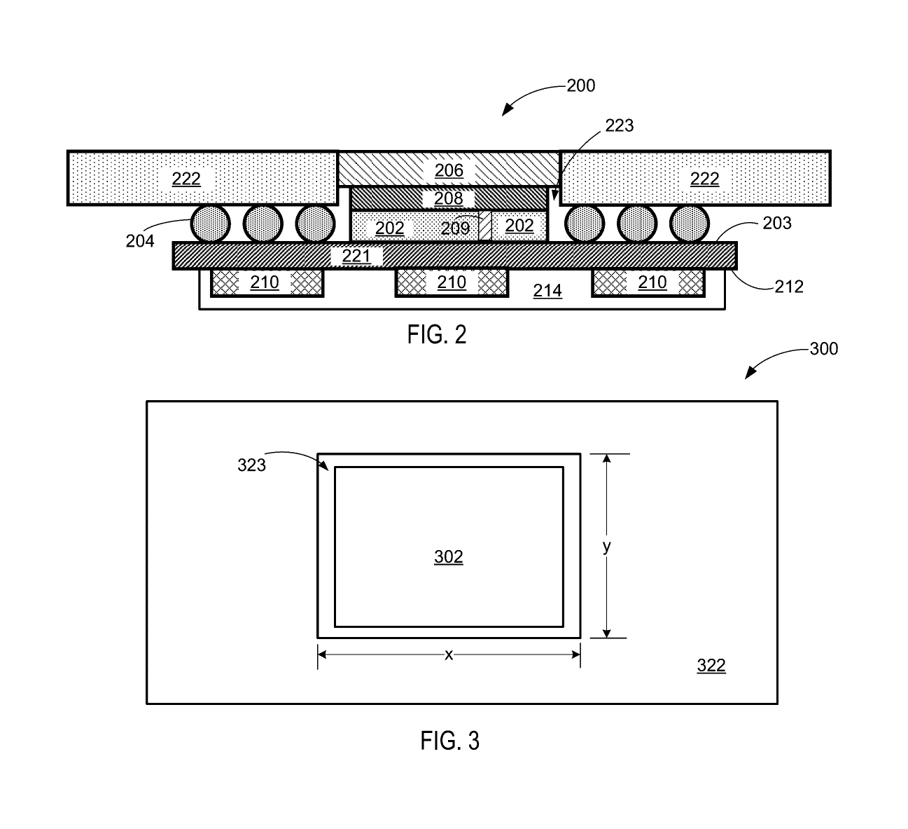

FIG. 2 schematically illustrates a cross-sectional side view of a board mounting configuration 200, in accordance with various embodiments. The board mounting configuration 200 may include a die 202 mounted to a top side 203 of a package assembly 221. The top side 203 of the package assembly 221 may be coupled with a circuit board 222 having a die cavity 223. In various embodiments, package-level interconnects such as solder balls 204 may be used to electrically and/or physically couple the package assembly 221 with the circuit board 222. The solder balls 204 may be composed of any suitable metal, alloy, or other conductive material. The package-level interconnects may be arranged in a regular pattern such as a BGA in various embodiments. Top-side connection pads or lands (not shown) may be present on the top side of the package assembly 221 in similar fashion to that described with respect to the top-side connection pads 109 of FIG. 1. Although the die 202 is shown to be below the circuit board 222, the die 202 may extend at least partially within the die cavity of the circuit board 222 in various embodiments.

A heat sink 206 that may be a copper board integrated heat sink (BIHS) in various embodiments may be located within the die cavity 223 of the circuit board 222 above the die 202. The heat sink 206 may be formed of another thermally conductive material, may be an active cooling system, or may be an active cooling agent in some embodiments. Thermal interface material (TIM) 208 may be disposed between the die 202 and the heat sink 206 to provide increased thermal conductivity between the die 202 and the heat sink 206 in some embodiments. In some embodiments, the die 202 may include at least one thermal through-silicon via (TSV) 209 to direct heat from the die 202 and/or the package assembly 221 to the heat sink 206. In some embodiments, the heat sink 206 and/or the TIM 208 may not be included.

In some embodiments, one or more additional dies 210 may be coupled with a bottom side 212 of the package assembly 221 opposite the top side 203. The additional dies 210 may include IC dies such as memory dies and/or radio frequency (RF) communication dies in various embodiments. The additional dies 210 may include sensors, gyroscopes, a geographic positioning system (GPS), and/or other system elements. A cover such as an encapsulating cover 214 may cover the additional dies 210 in some embodiments. In various embodiments, the additional dies 210 and/or the encapsulating cover 214 may not be included. The encapsulating cover 214 may be an overmold or another type of encapsulating cover such as a lid in some embodiments.

FIG. 3 schematically illustrates a top view of a board mounting configuration 300, in accordance with various embodiments. A circuit board 322 such as the circuit board 122 of FIG. 1 or the circuit board 222 of FIG. 2 is shown with a die cavity 323. In some embodiments, the die cavity 323 may extend in a first direction, which is designated as x, and in a second direction perpendicular to the first direction, which is designated as y. In various embodiments, the first direction and the second direction may be parallel to a top surface of a substrate or package assembly such as the package assembly 221 when it is mounted to the circuit board 322. Although the die cavity 323 is shown to be rectangular, any suitable shape may be used in various embodiments. A die 302 is shown to be positioned within a boundary of the die cavity 323 in both the first and second directions. The die 302 may be a die such as the die 102 or the die 202 in various embodiments. The die 302 may be below the circuit board 322 or may be at least partially within the die cavity 323 in various embodiments.

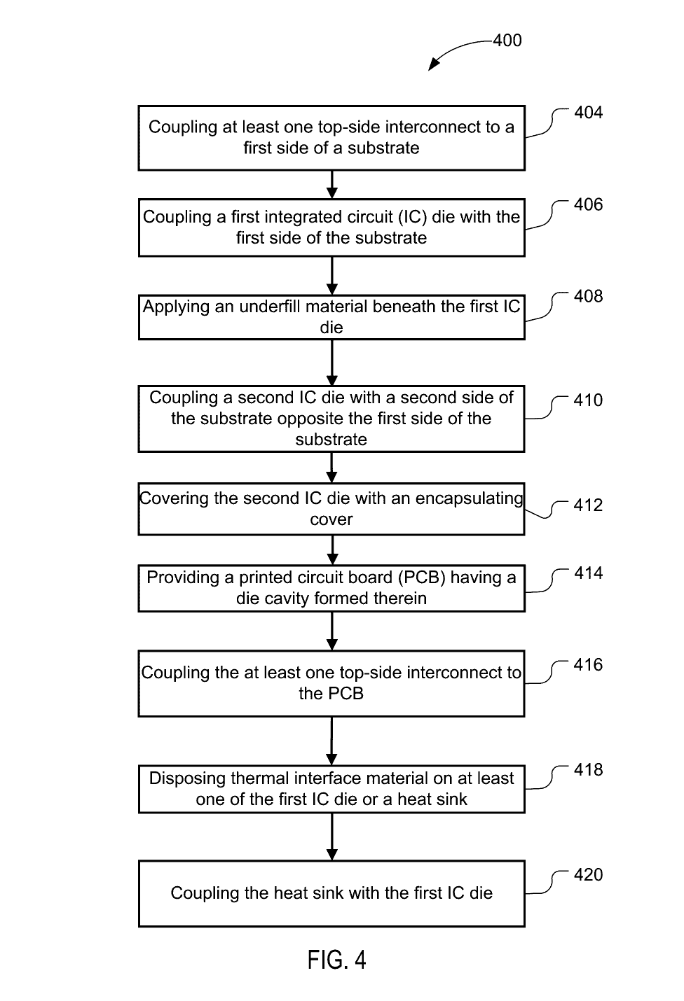

FIG. 4 schematically illustrates a flow diagram for a process 400 of fabricating an IC package assembly such as the IC package assembly of FIG. 1 and mounting it in a board mounting configuration such as that shown in FIGS. 2 and 3, in accordance with various embodiments. At a block 404, the process 400 may include coupling at least one top-side interconnect to a first side of a substrate. The at least one top-side interconnect may be package-level interconnects such as the solder balls 112 or the solder balls 204 described with respect to FIGS. 1 and 2 in various embodiments.

The process may continue at a block 406 with coupling a first IC die with the first side of the substrate. In various embodiments, the IC die may be a die such as the die 102, the die 202, or the die 302, and the substrate may be a substrate such as the package assembly 121 or the package assembly 221. In some embodiments, the process 400 may continue at a block 408 with applying an underfill material beneath the first IC die. The underfill material may be a material such as the underfill material 108 described with respect to FIG. 1 in various embodiments.

The process 400 may continue at a block 410 with coupling a second IC die with a second side of the substrate opposite the first side of the substrate. In various embodiments, the second IC die may be a die such as one of the additional dies 210 described with respect to FIG. 2. At a block 412, the process 400 may include covering the second IC die with an encapsulating cover such as the encapsulating cover 214 of FIG. 2.

At a block 414, the process 400 may include providing a PCB having a die cavity formed therein. The PCB may be a circuit board such as the circuit board 122, the circuit board 222, or the circuit board 322 in various embodiments. At a block 416, the process 400 may include coupling the at least one top-side interconnect to the PCB. The process 400 may continue with disposing TIM on at least one of the first IC die or a heat sink at a block 418. Disposing the TIM may include dispensing the TIM or otherwise placing the TIM in any suitable manner on at least one of the first IC die or the heat sink. At a block 420, the process 400 may include coupling the heat sink with the first IC die. In various embodiments, the heat sink may be a heat sink such as the heat sink 206 and the TIM may be similar to the TIM 208 described with respect to FIG. 2.

Embodiments of the present disclosure may be implemented into a system using the packages and manufacturing techniques disclosed herein. FIG. 5 schematically illustrates a computing device 500, in accordance with some implementations, which may include one or more IC package assemblies such as the IC package assembly 100 of FIG. 1 that may be configured in one or more board mounting configurations such as the board mounting configuration 200 or 300 of FIG. 2 or FIG. 3.

The computing device 500 may be, for example, a mobile communication device or a desktop or rack-based computing device. The computing device 500 may house a board such as a motherboard 502. The motherboard 502 may include a number of components, including (but not limited to) a processor 504 and at least one communication chip 506. Any of the components discussed herein with reference to the computing device 500 may include an IC package assembly such as the IC package assembly 100 that may be arranged in one or more board mounting configurations such as the board mounting configuration 200 or 300. In further implementations, the communication chip 506 may be part of a multi-die package such as that described with respect to the board mounting configuration 200 of FIG. 2.

The computing device 500 may include a storage device 508. In some embodiments, the storage device 508 may include one or more solid state drives. Examples of storage devices that may be included in the storage device 508 include volatile memory (e.g., dynamic random access memory (DRAM)), non-volatile memory (e.g., read-only memory, ROM), flash memory, and mass storage devices (such as hard disk drives, compact discs (CDs), digital versatile discs (DVDs), and so forth).

Depending on its applications, the computing device 500 may include other components that may or may not be physically and electrically coupled to the motherboard 502. These other components may include, but are not limited to, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, and a camera.

The communication chip 506 and the antenna may enable wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible broadband wireless access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 506 may operate in accordance with a Global System for Mobile Communications (GSM), General Packet Radio Service (GPRS), Universal Mobile Telecommunications System (UMTS), High Speed Packet Access (HSPA), Evolved HSPA (E-HSPA), or LTE network. The communication chip 506 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 506 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 506 may operate in accordance with other wireless protocols in other embodiments.

The computing device 500 may include a plurality of communication chips 506. For instance, a first communication chip 506 may be dedicated to shorter range wireless communications such as Wi-Fi and Bluetooth, and a second communication chip 506 may be dedicated to longer range wireless communications such as GPS, EDGE, GPRS, CDMA, WiMAX, LTE, EV-DO, and others. In some embodiments, the communication chip 506 may support wired communications. For example, the computing device 500 may include one or more wired servers.

The processor 504 and/or the communication chip 506 of the computing device 500 may include one or more dies or other components in an IC package. Such an IC package may be coupled with an interposer or another package using any of the techniques disclosed herein. The term “processor” may refer to any device or portion of a device that processes electronic data from registers and/or memory to transform that electronic data into other electronic data that may be stored in registers and/or memory.

In various implementations, the computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data. In some embodiments, the recessed conductive contacts disclosed herein may be implemented in a high-performance computing device.

The following paragraphs provide examples of various ones of the embodiments disclosed herein.

Example 1 may include a computing device comprising: a printed circuit board (PCB) having a die cavity formed therein; a substrate having a first side with a plurality of connection pads electrically coupled with the PCB, and a second side opposite the first side; and an integrated circuit (IC) die coupled with the first side of the substrate, wherein the die is positioned such that it is within a boundary of the die cavity in a first direction parallel with the first side of the substrate and a second direction parallel with the first side of the substrate and perpendicular to the first direction, and the IC die is electrically coupled with one or more of the plurality of connection pads.

Example 2 may include the subject matter of Example 1, further comprising a plurality of interconnect structures coupled with the plurality of connection pads and the PCB.

Example 3 may include the subject matter of Example 2, wherein the plurality of interconnect structures are solder balls.

Example 4 may include the subject matter of Example 1, further comprising a heat sink coupled with the IC die.

Example 5 may include the subject matter of Example 4, wherein the die includes one or more thermal through-silicon vias.

Example 6 may include the subject matter of Example 4, further comprising thermal interface material between the IC die and the heat sink.

Example 7 may include the subject matter of Example 4, wherein the heat sink is a copper board-integrated heat sink.

Example 8 may include the subject matter of Example 4, wherein the heat sink is located within the die cavity of the PCB.

Example 9 may include the subject matter of any one of Examples 1-8, wherein the IC die is a first IC die and the computing device further comprises a second IC die coupled with the second side of the substrate, wherein the second IC die is electrically coupled with one or more of the plurality of connection pads.

Example 10 may include the subject matter of Example 9, further comprising a cover coupled with the second IC die.

Example 11 may include an integrated circuit (IC) package assembly comprising: a substrate having a first side and a second side opposite the first side; an IC die coupled with the first side of the substrate; a plurality of connection pads coupled with the first side of the substrate; and a plurality of interconnect structures coupled with the plurality of connection pads, wherein the IC die is electrically coupled with one or more of the plurality of connection pads and wherein the plurality of interconnect structures are arranged in a ball grid array (BGA).

Example 12 may include the subject matter of Example 11, wherein the IC die is a processor die.

Example 13 may include the subject matter of Example 11, wherein the plurality of interconnect structures are solder balls.

Example 14 may include the subject matter of any one of Examples 11-13, wherein the IC die is a first IC die and the IC package assembly further comprises a second IC die coupled with the second side of the substrate, wherein the second IC die is electrically coupled with one or more of the plurality of connection pads.

Example 15 may include the subject matter of Example 14, further comprising an overmold coupled with the second IC die.

Example 16 may include the subject matter of Example 14, wherein the second IC die is a memory die.

Example 17 may include a method of fabricating a computing device comprising: providing a printed circuit board (PCB) having a die cavity formed therein; coupling at least one top-side interconnect to a first side of a substrate; coupling an integrated circuit (IC) die with the first side of the substrate; and coupling the at least one top-side interconnect to the PCB, wherein the die is positioned within a boundary of the die cavity in a first direction parallel with the first side of the substrate and a second direction parallel with the first side of the substrate and perpendicular to the first direction.

Example 18 may include the subject matter of Example 17, further comprising applying an underfill material beneath the die after coupling the die with the first side of the substrate.

Example 19 may include the subject matter of Example 17, further comprising coupling a heat sink with the die.

Example 20 may include the subject matter of Example 19, further comprising disposing thermal interface material on at least one of the die or the heat sink before coupling the heat sink with the die.

Example 21 may include the subject matter of any one of Examples 19-20, wherein the heat sink is a copper board-integrated heat sink.

Example 22 may include the subject matter of any one of Examples 19-20, wherein the heat sink is located within the die cavity of the PCB.

Example 23 may include the subject matter of any one of Examples 17-20, wherein the IC die is a first IC die and the method further comprises coupling a second IC die with a second side of the substrate opposite the first side of the substrate.

1. A computing device comprising:
a printed circuit board (PCB) having a die cavity formed therein;
a substrate having a first side with a plurality of connection pads electrically coupled with the PCB, and a second side opposite the first side; and
a first integrated circuit (IC) die coupled with the first side of the substrate, wherein the first IC die is positioned such that it is within a boundary of the die cavity in a first direction parallel with the first side of the substrate and a second direction parallel with the first side of the substrate and perpendicular to the first direction, and the first IC die is electrically coupled with one or more of the plurality of connection pads; and
a second IC die coupled with the second side of the substrate, wherein the second IC die is a radio frequency (RF) communication die electrically coupled with one or more of the plurality of connection pads.

2. The computing device of claim 1, further comprising a plurality of interconnect structures coupled with the plurality of connection pads and the PCB.

3. The computing device of claim 2, wherein the plurality of interconnect structures are solder balls.

4. The computing device of claim 1, further comprising a heat sink coupled with the first IC die.

5. The computing device of claim 4, wherein the first IC die includes one or more thermal through-silicon vias.

6. The computing device of claim 4, further comprising thermal interface material between the first IC die and the heat sink.

7. The computing device of claim 4, wherein the heat sink is an active cooling system.

8. The computing device of claim 5, wherein the heat sink is a copper board-integrated heat sink located within the die cavity of the PCB.

9. The computing device of claim 8, comprising a third IC die coupled with the second side of the substrate, wherein the third IC die is a memory die electrically coupled with one or more of the plurality of connection pads.

10. The computing device of claim 9, further comprising a cover coupled with the second IC die and the third IC die.

11. An integrated circuit (IC) package assembly comprising:
a substrate having a first side and a second side opposite the first side;
a first IC die coupled with the first side of the substrate;
a second IC die coupled with the second side of the substrate;
a third IC die coupled with the second side of the substrate;
a plurality of connection pads coupled with the first side of the substrate; and
a plurality of interconnect structures coupled with the plurality of connection pads,
wherein the first IC die and the second IC die are electrically coupled with one or more of the plurality of connection pads and wherein the plurality of interconnect structures are arranged in a ball grid array (BGA).

12. The IC package assembly of claim 11, wherein the first IC die is a processor die.

13. The IC package assembly of claim 11, wherein the plurality of interconnect structures are solder balls.

14. The IC package assembly of claim 12, wherein the second IC die is a radio frequency (RF) communication die.

15. The IC package assembly of claim 14, further comprising an overmold coupled with the second IC die and the third IC die.

16. The IC package assembly of claim 15, wherein the third IC die is a memory die.

17. A method of fabricating a computing device comprising:
providing a printed circuit board (PCB) having a die cavity formed therein;
coupling at least one top-side interconnect to a first side of a substrate;
coupling a first integrated circuit (IC) die with the first side of the substrate;
coupling a second IC die with a second side of the substrate opposite the first side of the substrate, wherein the second IC die is a radio frequency (RF) communication die; and
coupling the at least one top-side interconnect to the PCB, wherein the first IC die is positioned within a boundary of the die cavity in a first direction parallel with the first side of the substrate and a second direction parallel with the first side of the substrate and perpendicular to the first direction.

18. The method of claim 17, further comprising applying an underfill material beneath the first IC die after coupling the first IC die with the first side of the substrate.

19. The method of claim 17, further comprising coupling a heat sink with the first IC die.

20. The method of claim 19, further comprising disposing thermal interface material on at least one of the first IC die or the heat sink before coupling the heat sink with the first IC die.

21. The method of claim 19, wherein the heat sink is an active cooling system.

22. The method of claim 19, wherein the heat sink is a copper board-integrated heat sink located within the die cavity of the PCB.

23. The method of claim 22, further comprising coupling a third IC die with the second side of the substrate.
